(19) United States
(12) Patent Application Publication
(10) Pub. No.: US 2015/0221739 A1
(43) Pub. Date: Aug. 6, 2015

(54) PIXEL ELECTRODE, DISPLAY DEVICE, METHOD OF MANUFACTURING PIXEL ELECTRODE

(71) Applicant: SEIKO EPSON CORPORATION, Tokyo (JP)

(72) Inventor: Takashi MIYATA, Shiojiri (JP)

(21) Appl. No.: 14/606,112

(22) Filed: Jan. 27, 2015

(30) Foreign Application Priority Data
Jan. 31, 2014 (JP) 2014-016642

(51) Int. Cl. H01L 29/45; H01L 21/283

(52) U.S. Cl. CPC H01L 29/45; H01L 21/283

(57) ABSTRACT

A pixel electrode used in a display device having a display layer provided between a pair of substrates, includes a first layer having a first surface in contact with the display layer, and a second layer in contact with a second surface opposed to the first surface of the first layer, wherein an electrode potential of the first layer is lower than an electrode potential of the second layer.

This application claims a priority to Japanese Patent Application No. 2014-016642 filed on Jan. 31, 2014 which is hereby expressly incorporated by reference in its entirety.

### BACKGROUND

1. Technical Field

Several aspects of the present invention relate to a pixel electrode, a display device, a method of manufacturing a pixel electrode.

2. Related Art

In flat panel display devices such as a liquid crystal display device, generally, display lights (including modulated transmission lights and reflection lights etc.) are controlled with respect to each pixel using pixel electrodes, and thereby, an image is formed. In transmissive display devices such as a liquid crystal display device, as materials for forming the pixel electrodes, transparent conducting materials of ITO (indium oxide-tin alloy) and IZO (indium oxide-zinc alloy) have been used in view of light transmissivity and corrosion resistance.

On the other hand, in reflective display devices such as an electrophoretic display device, of a pair of electrodes, one electrode located at the opposite side to the display surface does not require transmissivity, but preferably has reflectivity. Accordingly, for example, as shown in Patent Document 1 (JP-A-2009-230061), an electrooptical device having the one electrode of a conducting film in which an Al (aluminum) film and a thin film formed using a material containing aluminum oxide in molybdenum are stacked is proposed.

However, there is a problem that the electrode of the above described conducting film easily corrodes (dissolves) in contact with a liquid containing electrolyte and durability and reliability may be lower.

### SUMMARY

An advantage of some aspects of the invention is to solve at least a part of the problems described above, and the invention can be implemented as the following forms or application examples.

### Application Example 1

This application example is directed to a pixel electrode used in a display device having a display layer provided between a pair of substrates, and including a first layer having a first surface in contact with the display layer, and a second layer in contact with a second surface opposed to the first surface of the first layer, wherein an electrode potential of the first layer is lower than an electrode potential of the second layer.

According to this application example, when a voltage is applied to the pixel electrode, a flow of electrons is generated within the pixel electrode from the first layer having the lower electrode potential to the second layer having the higher electrode potential. As a result, oxidation reaction occurs in the first layer and reduction reaction occurs in the second layer. In this case, even when the display layer contains electrolyte, delivery and receipt of electrons via the display layer may be limited by appropriate setting of the exposed area of the second layer, and the oxidation reaction of the first layer, i.e., dissolution with respect to the display layer may be suppressed. Therefore, even when a metal material having dissolubility and higher reflectivity is used for the first layer, durability of the pixel electrode may be secured, and the pixel electrode that may achieve both higher display performance and reliability may be realized.

### Application Example 2

This application example is directed to the pixel electrode according to the application example described above, wherein an end portion of the second layer is not covered by the first layer.

According to this application example, movement of electrons from the first layer to the second layer can be suppressed and dissolution with respect to the display layer can be suppressed.

### Application Example 3

This application example is directed to the pixel electrode according to the application example described above, wherein a hole penetrating the first layer and the second layer is formed.

According to this application example, the exposed area of the second layer can be set regardless of the layer thickness of the second layer. Therefore, the layer thickness of the second layer can be optionally set, and the pixel electrode with higher display performance can be realized without damaging reliability.

### Application Example 4

This application example is directed to the pixel electrode according to the application example described above, wherein a thickness of the first layer is larger than a thickness of the second layer.

According to this application example, the pixel electrode can be formed without unnecessarily increasing the exposed area of the second layer.

### Application Example 5

This application example is directed to the pixel electrode according to the application example described above, wherein the first layer is formed using Al or an Al alloy.

The Al or the Al alloy has higher reflectivity. Therefore, according to this application example, the pixel electrode with higher display performance can be realized without damaging reliability.

### Application Example 6

This application example is directed to the pixel electrode according to the application example described above, wherein the second layer is formed using Ti or a Ti alloy.

According to this application example, the Ti or the Ti alloy has the higher electrode potential. Therefore, according to the configuration, dissolution of the first layer can be suppressed.

### Application Example 7

This application example is directed to a display device including the pixel electrode according to any one of the application examples described above.

According to this application example, the pixel electrode is provided, and the display device in which both higher display performance and reliability are achieved can be realized.

### Application Example 8

This application example is directed to the display device according to the application example described above, which further includes a mounting terminal formed by the first layer and the second layer.

The mounting terminal is formed at the same step as that of the above described pixel electrode. The mounting terminal has higher durability than a mounting terminal including only the first layer having the higher reflectivity. Therefore, according to this application example, the display device having the mounting terminal with higher reliability can be realized without increasing manufacturing cost.

### Application Example 9

This application example is directed to a method of manufacturing a pixel electrode including forming a second conductor layer on an insulating layer, forming a first conductor layer of a material having an electrode potential lower than an electrode potential of a formation material of the second conductor layer on the second conductor layer, and forming an island-shaped electrode by collectively patterning the first conductor layer and the second conductor layer.

According to this application example, the pixel electrode may be formed without unnecessarily increasing the exposed area of the second conductor layer. Further, the number of steps of patterning may be reduced. Therefore, the pixel electrode with higher display performance may be manufactured without increasing manufacturing cost.

### BRIEF DESCRIPTION OF THE DRAWINGS

The invention will be described with reference to the accompanying drawings, wherein like numbers reference like elements.

FIG. 1 is a schematic perspective view showing a configuration of an electrophoretic display device.

FIG. 2 is a schematic sectional view showing structures of pixels etc. in the electrophoretic display device.

FIGS. 3A to 3C schematically show a pixel electrode according to the first embodiment, and FIG. 3A is a plan view, FIG. 3B is a sectional view along line A-A in FIG. 3A, and FIG. 3C is an enlarged view of a part shown by B in FIG. 3B.

FIG. 4 shows a result from application of rectangular wave to a pixel electrode having a smaller exposed area of a Ti layer in a predetermined time.

FIG. 5 shows a result from application of rectangular wave to a pixel electrode having a larger exposed area of a Ti layer in a predetermined time.

FIGS. 6A and 6B show sections of pixel electrodes used for the experiments, and FIG. 6A is a sectional view of the pixel electrode having the smaller exposed area of a Ti layer and FIG. 6B is a sectional view of the pixel electrode having the larger exposed area of the Ti layer.

FIGS. 7A to 7D are diagrams of steps showing a method of manufacturing the pixel electrode.

FIGS. 8A to 8C show pixel electrodes according to the third to fifth embodiments, and FIG. 8A shows the pixel electrode according to the third embodiment, FIG. 8B shows the pixel electrode according to the fourth embodiment, and FIG. 8C shows the pixel electrode according to the fifth embodiment.

FIGS. 9A and 9B show a mounting terminal according to the sixth embodiment with a comparative example, and FIG. 9A shows the mounting terminal according to the sixth embodiment in which an Al layer and a Ti layer are stacked and FIG. 9B shows amounting terminal of the comparative example.

### DESCRIPTION OF EXEMPLARY EMBODIMENTS

As below, embodiments in which the invention is embodied will be explained with reference to the drawings. Note that, in the drawings for use, the explained parts are appropriately scaled up and down to be recognizable.

In the following embodiments, for example, the description “on substrate” represents the case where a configuration is provided on the substrate in contact, the case where a configuration is provided on the substrate via another configuration, or the case where a part of a configuration is provided on the substrate in contact and another part of the configuration is provided via another configuration.

### First Embodiment

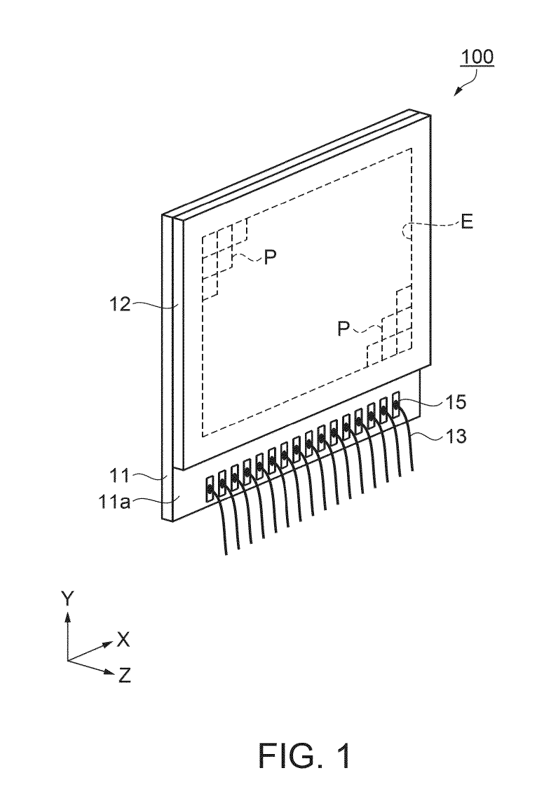

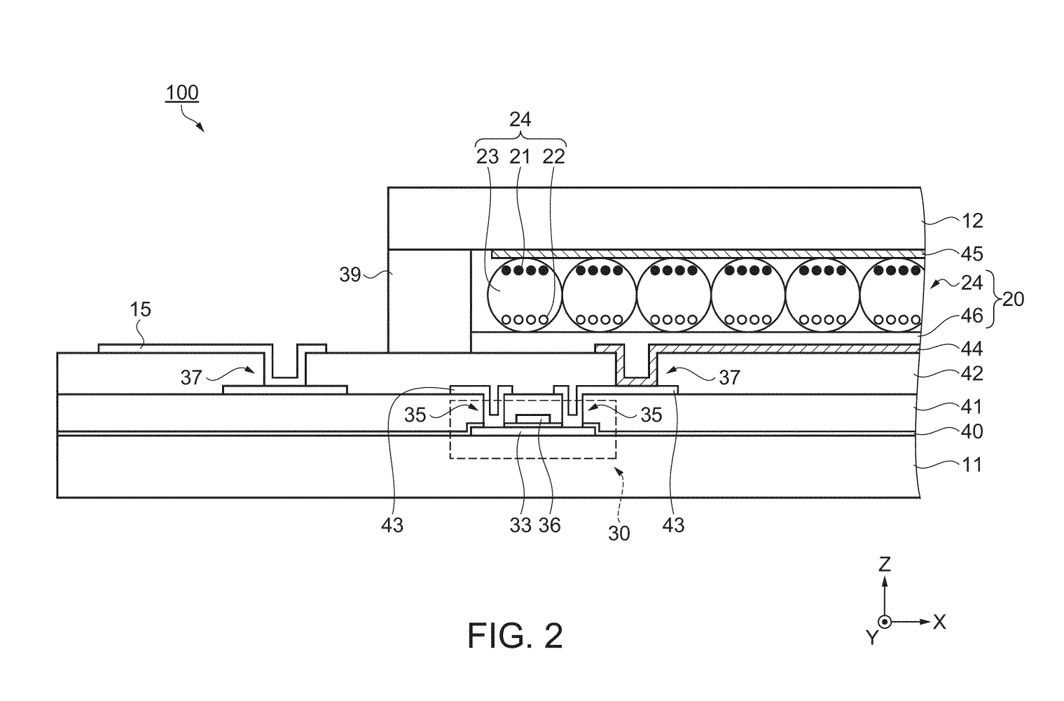

First, prior to the explanation of a pixel electrode according to the embodiment, a display device using the pixel electrode will be explained using FIGS. 1 and 2 by taking an electrophoretic display device as an example. FIG. 1 is a schematic perspective view showing a configuration of the electrophoretic display device, and FIG. 2 is a schematic sectional view showing structures of pixels etc. in the electrophoretic display device.

### Electrophoretic Display Device

As shown in FIG. 1, the electrophoretic display device 100 as the display device of the embodiment has a device substrate 11 and an opposed substrate 12 provided to face each other. Further, an electrophoretic layer 20 (see FIG. 2) as a display layer is provided between the pair of substrates. Note that, in the embodiment, both of the pair of substrates are rectangular, but not limited to the shape.

The electrophoretic layer 20 has a plurality of regions sectioned in a matrix form between the pair of substrates and the respective plurality of regions have functions as pixels P. That is, the plurality of pixels P arranged in the matrix form a display region E.

In the embodiment, the explanation will be made, in the display region E, with the row direction of the pixels P arranged in the matrix form as the X-direction, the column direction of the pixels P as the Y-direction, and a direction directed from the device substrate 11 to the opposed substrate 12 side and orthogonal to the X-direction and the Y-direction as the Z-direction. Further, a view seen from the opposed substrate 12 in the Z-direction is referred to as “plan view”.

The arrangement pattern of the pixels P is not limited to the matrix form, but, for example, a delta-form arrangement pattern may be employed.

Here, the device substrate 11 is larger than the opposed substrate 12 at one side of the four sides. When the device substrate 11 and the opposed substrate 12 are placed to face each other in predetermined locations, the portion of the device substrate 11 protruding from the opposed substrate 12 is a terminal portion 11a. Further, mounting terminals 15 are provided in the terminal portion 11a. Furthermore, bonding wires 13 are connected to the mounting terminals 15.

As will be described later, the electrophoretic display device 100 is a light receiving-type device in which display is recognized using light applied from outside. Further, the electrophoretic display device 100 has transistors for switching control of the pixel P at the device substrate 11 side, wires connecting to the transistors, etc., and the mounting terminals 15 are connected to the wires etc. Therefore, the electrophoretic display device 100 is driven by signals and power supply from external circuits transmitted via the mounting terminals 15.

FIG. 2 is a schematic sectional view in the X-direction of FIG. 1 showing a schematic configuration of the electrophoretic display device 100. The illustration of the bonding wires 13 is omitted. As shown in FIG. 2, the electrophoretic display device 100 includes the electrophoretic layer 20 provided between the device substrate 11 and the opposed substrate 12, a thin-film transistor (hereinafter, referred to as “TFT”) 30 formed on the device substrate 11, etc.

The device substrate 11 is formed using an insulating material of glass, plastic, or the like. As described above, the electrophoretic display device 100 is the reflective display device, and the device substrate 11 does not require light transmissivity. Therefore, the device substrate may be formed using a material not having light transmissivity such as ceramic.

The opposed substrate 12 is provided at the display surface side and requires light transmissivity, and is formed using a light-transmissive material of a glass substrate or the like.

The TFT 30 is formed on the device substrate 11. The TFT 30 includes a semiconductor layer 33 patterned in an island shape, a gate insulating film 40 formed to cover nearly the entire surface of the device substrate 11 including the semiconductor layer 33, and a gate electrode 36.

The semiconductor layer 33 is formed using e.g., polycrystalline silicon, and sectioned into a channel region and a source-drain region by differences in concentration of implanted impurities (not shown). The region superimposed on the gate electrode 36 is the channel region and the regions on both sides is the source-drain region. The TFT 30 is covered by a first interlayer insulating film 91. The first interlayer insulating film 41 is formed using e.g., oxide and nitride of silicon.

In regions superimposed on the source-drain region in the first interlayer insulating film 41, first contact holes 35 are formed. The first contact holes 35 are formed by locally etching the first interlayer insulating film 41 using a photolithography technology. In the embodiment, all of the contact holes formed in the first interlayer insulating film 41 are the first contact holes 35. Further, relay layers 43 connected to the source-drain region via the first contact holes 35 are formed on the first interlayer insulating film 41. In the embodiment, all of the wires (layers) formed between the first interlayer insulating film 41 and a second interlayer insulating film 42, which will be described later, are referred to as the relay layers 43. Specifically, the relay layers 43 are source lines, relay electrodes, or the like. The relay layers 43 are formed using an Al alloy or the like by collectively patterning the same material layer using a photolithography technology.

On the device substrate 11 on which the source lines and the relay layers 43 are formed, the second interlayer insulating film 42 of acrylic resin is formed. Second contact holes 37 are formed in regions of the second interlayer insulating film 42 superimposed on the relay layers 43. In the embodiment, all of the contact holes formed in the second interlayer insulating film 42 are the second contact holes 37.

Like the above described first contact holes 35, the second contact holes 37 are formed by locally etching the second interlayer insulating film 42 using a photolithography technology. Here, if a light-sensitive resin material is used for the acrylic resin, the step of forming a resist layer may be omitted.

Further, on the second interlayer insulating film 42, a pixel electrode 44 connected to the TFT 30 via the second contact hole 37 and the relay layer 43 is formed. The pixel electrode 44 is a conducting material layer patterned in an island shape, and formed with respect to each of the above described pixels P (see FIG. 1). The specific configuration of the pixel electrode 44 will be described later.

Further, on the second interlayer insulating film 42 (strictly, between the second interlayer insulating film 42 and the opposed substrate 12), a seal material 39 is formed. The seal material 39 is an adhesive, e.g., thermosetting or ultraviolet-curable epoxy resin, and formed along the outer edge of the opposed substrate 12. That is, the seal material 39 is annularly formed to surround the display region E in the plan view. Therefore, the device substrate 11 and the opposed substrate 12 are provided to face each other via the seal material 39. Further, the electrophoretic layer 20 is within the space formed by the pair of substrates of the device substrate 11 and the opposed substrate 12 and the seal material 39.

Furthermore, on the second interlayer insulating film 42, the mounting terminal 15 is also formed. As described above, the device substrate 11 is larger on one side than the opposed substrate 12, and the side protrudes from the seal material 39. The mounting terminal 15 is formed in the protruding region and formed at the same step as that for the pixel electrode 44 in the embodiment. The mounting terminal 15 will be described later.

More specifically, the electrophoretic layer 20 is provided between electrodes formed on both of the pair of substrates. That is, the electrophoretic layer is provided between the pixel electrode 44 formed on the device substrate 11 and an opposed electrode 45 formed on the opposed substrate 12. The opposed electrode 45 requires light transmissivity like the opposed substrate 12, and is formed using a transparent conducting material, e.g., ITO (Indium Tin Oxide) or the like. Unlike the pixel electrode 44, the opposed electrode is formed nearly in the entire display region E without sections. Therefore, the opposed electrode 45 functions as a common electrode for all of the pixels P provided in the display region E. Note that, in the embodiment, the opposed electrode 45 is formed inside of the seal material 39, however, the opposed electrode 45 and the seal material 39 may overlap on the outer edge of the opposed substrate 12.

As described above, the pixel electrode 44 is formed with respect to each pixel P and individually controllable by the TFT 30. Therefore, in the electrophoretic display device 100, voltages are optionally applied between the pixel electrodes 44 and the opposed electrodes 45 with respect to each pixel P.

The electrophoretic layer 20 includes microcapsules 24 and an adhesive layer 46. The adhesive layer 46 is a sheet-like base material having both adhesive surfaces, and the microcapsules 24 are spread all over one surface in a single layer to minimize gaps. The other surface is bonded onto the device substrate 11 with the pixel electrode 44 formed thereon. The adhesive layer 46 contains electrolyte.

The microcapsules 24 have diameters of about 30 μm to 75 μm and, as shown in the drawing, arranged between the pixel electrode 44 and the opposed electrode 45 in a matrix form in one (single) layer in the Z-direction in contact with each other in the X-direction and the Y-direction. Therefore, the diameters of the microcapsules 24 are nearly equal to the dimension between the pixel electrode 44 and the opposed electrode 45. Further, nearly the equal number of microcapsules 24 are provided on the respective pixel electrodes 44.

The microcapsule 24 has a spherical body in which a plurality of electrophoretic particles and a dispersion medium 23 are encapsulated. The electrophoretic particles include black electrophoretic particles (hereinafter, referred to as “black particles”) 21 and white electrophoretic particles (hereinafter, referred to as “white particles”) 22. Within the microcapsule 24, the respective same number of black particles 21 and the white particles 22 are encapsulated. Further, the outer shell part (wall film) of the microcapsule is formed using a polymeric resin having light transmissivity including acrylic resin such as polymethyl methacrylate, polyethyl methacrylate, urea resin, and gum arabic.

As the dispersion medium 23, water, alcoholic solvents (methanol, ethanol, isopropanol, butanol, octanol, methyl cellosolve, etc.), esters (ethyl acetate, butyl acetate), ketones (acetone, methyl ethyl ketone, methyl isobutyl ketone, etc.), aliphatic hydrocarbons (pentane, hexane, octane, etc.), alicyclic hydrocarbons (cyclohexane, methylcyclohexane, etc.), aromatic hydrocarbons (benzene, toluene, benzenes having long-chain alkyl groups (xylene, hexyl benzene, hebutylbenzene, octylbenzene, nonylbenzene, decylbenzene, undecylbenzene, dodecylbenzene, tridecylbenzene, tetradecylbenzene, etc.)), halogenated hydrocarbons (methylene chloride, chloroform, carbon tetrachloride, 1,2-dichloroethane, etc.), carboxylates, etc. may be exemplified. Further, for example, oils including silicone oil may be used. These materials may be used singly or as mixture.

The black particles 21 are particles (polymer or colloid) consisting of black pigments e.g., aniline black, carbon black, or the like. The white particles 22 are particles (polymer or colloid) consisting of white pigments e.g., titanium dioxide, zinc oxide, antimony trioxide, or the like. As necessary, electrolyte, surfactant agent, metal soap, resin, rubber, oil, varnish, charge control agent consisting of particles of compound, a dispersant agent such as titanium-based coupling agent, aluminum-based coupling agent, or silane-based coupling agent, a lubricant agent, a stabilizing agent, etc. may be added to these pigments.

Further, the black particles 21 and the white particles 22 are charged to have opposite potentials to each other and used. When the black particles 21 are positively charged and used, the white particles 22 are negatively charged and used. Then, by utilizing the potential differences, voltages are applied between the pixel electrodes 44 and the opposed electrodes 45 with respect to each pixel P, and thereby, an image may be formed in the display region E.

FIG. 2 shows the case where the illustrated pixel P presents black. In the case of black presentation, a direct-current drive voltage is applied between the pixel electrode 44 and the opposed electrode 45, and the opposed electrode 45 is held at the lower potential and the pixel electrode 44 is held at the higher potential. Thereby, the positively charged black particles 21 are attracted to the opposed electrode 45 and the negatively charged white particles 22 are attracted to the pixel electrode 44. As a result, when the pixel P is seen from the opposed electrode 45 (opposed substrate) side, black is recognized.

In the case of white presentation, a direct-current drive voltage may be applied between the pixel electrode 44 and the opposed electrode 45 so that the opposed electrode 45 may be at the higher potential and the pixel electrode 44 may be at the lower potential. Thereby, the negatively charged white particles 22 are attracted to the opposed electrode 45 and the positively charged black particles 21 are attracted to the pixel electrode 44. As a result, when the pixel P is seen from the opposed electrode 45 side, white is recognized.

Note that, in place of the black particles 21 and the white particles 22, for example, particles using pigments of red, green, blue, etc. may be used. According to the configuration, color presentation may be performed.

As described above, in the electrophoretic display device 100, image display is performed by application of voltages to the pixel electrodes 44. Further, the pixel electrodes 44 (or the opposed electrodes 45) are in contact with the electrophoretic layer 20, specifically, the adhesive layers 46 and the microcapsules 24. Here, the adhesive layers 46 contain electrolyte as described above.

On the other hand, the pixel electrode 44 does not require light transmissivity unlike the opposed electrode 45, but requires reflectivity (light reflectivity) for improvement of display performance. Therefore, it is preferable to form the pixel electrode 44 using an Al-based material having higher reflectivity. However, when a voltage is applied to the Al-based material in contact with a material containing electrolyte, electrode reaction occurs and corrosion or the like may be caused. In the pixel electrode 44 of the embodiment, two kinds of materials having different electrode potentials are stacked, and thereby, the display performance is improved, the above described corrosion or the like is suppressed, and the reliability is improved.

### Pixel Electrode

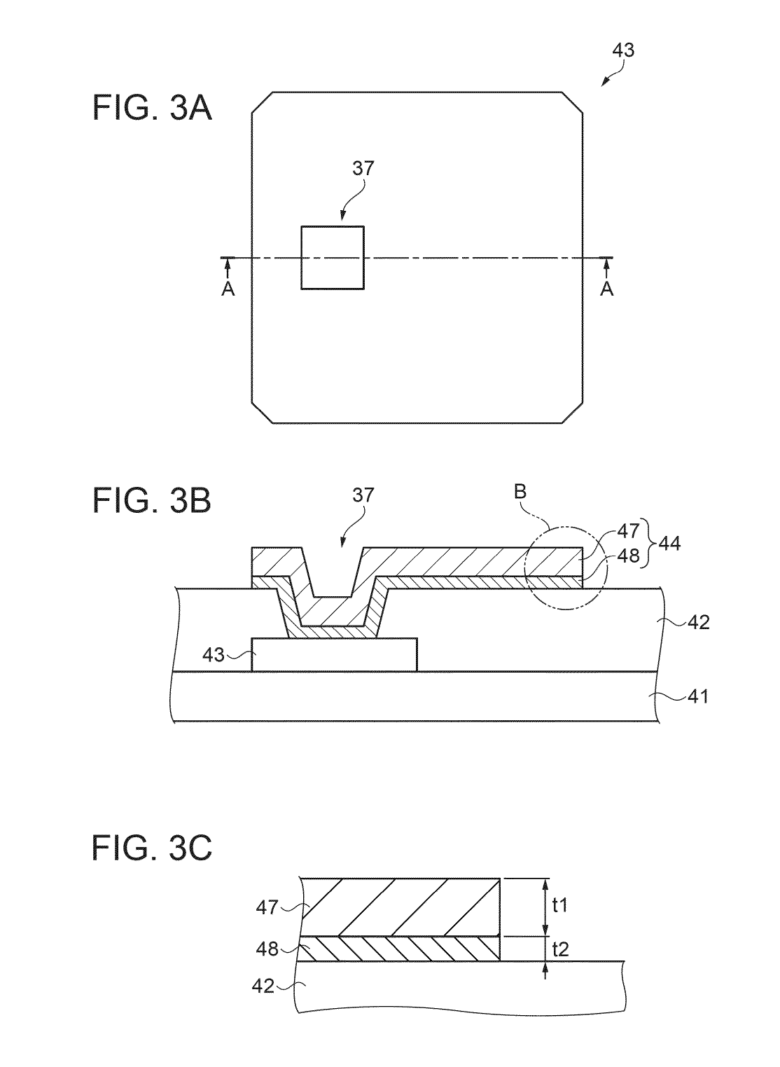

FIGS. 3A to 3C schematically show the pixel electrode 44 according to the embodiment, and FIG. 3A is a plan view, FIG. 3B is a sectional view along line A-A in FIG. 3A, and FIG. 3C is an enlarged view of a part shown by B in FIG. 3B.

As shown in FIG. 3A, the pixel electrode 44 has a nearly square planar shape with one side of about 100 μm. The planar shape of the pixel electrode 44 is not limited to the square shape, but may be a rectangular shape, another polygonal shape than square, a circular shape, or the like.

As shown in FIG. 3B, the pixel electrode 44 is formed by stacking two layers of different materials from each other. The layers include the upper layer, i.e., a first layer 47 in contact with the electrophoretic layer 20 and the lower layer, i.e., a second layer 48 in contact with the second interlayer insulating film 42. In the invention, the first layer 47 is formed using a material having the lower electrode potential than the electrode potential of the second layer 48. In other words, the electrode potential of the first layer 47 is lower than the electrode potential of the second layer 98. Further, in the embodiment, the first layer 47 is formed using Al (aluminum) or an Al alloy and the second layer 48 is formed using Ti (titanium) or a Ti alloy. Hereinafter, the first layer 47 is referred to as “Al layer 47” and the second layer 48 is referred to as “Ti layer 48”. The electrode potentials of the respective layers are based on the electrode potential at redox of hydrogen (0 V), and, for example, −1.70 V for Al (aluminum) and −1.63 V for Ti (titanium).

Here, as the Al alloy, an Al—Cu (copper) alloy, an Al—Nd (neodymium) alloy, or the like may be preferably used. Further, as the Ti alloy, TiN (titanium nitride) may be preferably used. In the following description, “Al or Al alloy” may be collectively referred to as Al and “Ti or Ti alloy” may be collectively referred to as Ti.

As shown in FIG. 3C, the layer thickness t1 of the Al layer 47 is formed to be larger than the layer thickness t2 of the Ti layer 48. Specifically, t1 is about 300 nm and t2 is about 100 nm. The layer thickness of the Al layer 47 may be preferably used in a range from 200 nm to 600 nm. Further, the layer thickness of the Ti layer 48 may be preferably used in a range from 50 nm to 100 nm.

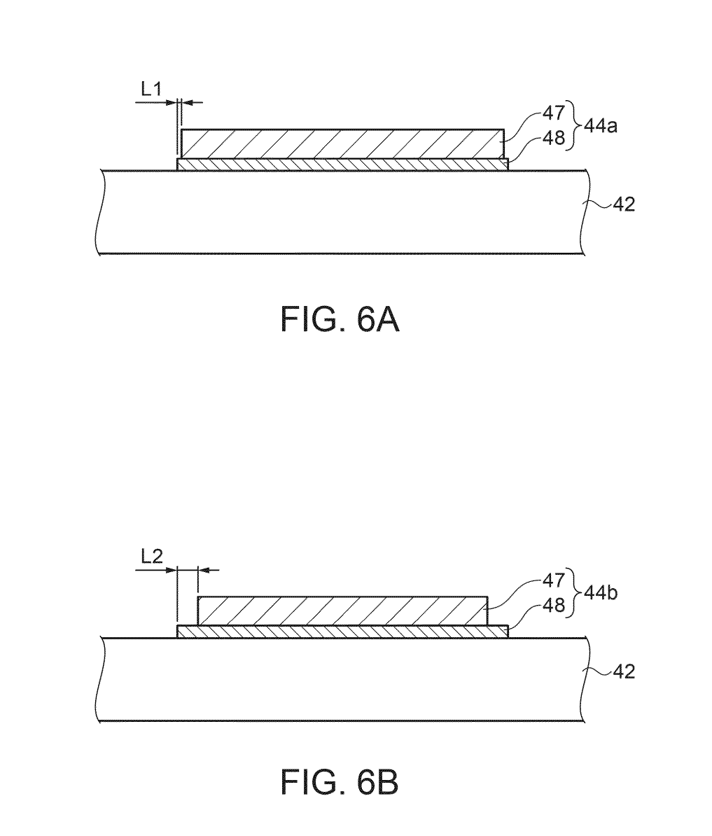

Here, regarding the exposed regions of both layers (Al layer 47 and Ti layer 48) in the pixel electrode 44, the entire upper surface and the end portion of the Al layer 47 are exposed, and only the end portion of the Ti layer 48 is exposed. That is, the exposed area of the Ti layer 48 is suppressed to be extremely smaller than the exposed area of the Al layer 47. Note that, as shown in FIG. 6 to be described later, actually, the upper surface of the Ti layer 48 may be slightly exposed.

Here, Al is a metal having the lower electrode potential, i.e., less noble metal than Ti. Ti is a noble metal. Further, as described above, the adhesive layer 46 contains electrolyte. Therefore, when a voltage is applied to the pixel electrode 44, a flow of electrons from the Al layer 47 of the less-noble metal to the Ti layer 48 of the noble metal is generated within the pixel electrode 44. Accordingly, oxidation reaction (Al→Al₃⁺+3e⁻: dissolution) may occur in the Al layer 47 and reduction reaction (2O₂+4H⁺+4e⁻→4OH⁻) may occur in the Ti layer 48. However, when the exposed area of the Al layer 47 in the surface area of the pixel electrode 44 is extremely large, i.e., the exposed area of the Al layer 47 is extremely larger than the exposed area of the Ti layer 48, delivery and receipt of electrons from the Al layer 47 to the exposed Ti layer 48 via the electrophoretic layer 20 are not sufficiently performed, and the redox reaction is suppressed. That is, the dissolution of the Al layer 47 is suppressed. Therefore, according to the pixel electrode 44 having the configuration, dissolution (corrosion) at voltage application may be suppressed with the higher reflectivity than that of the Ti layer 48 kept, and both higher display performance and reliability may be achieved.

### Advantages of Embodiment

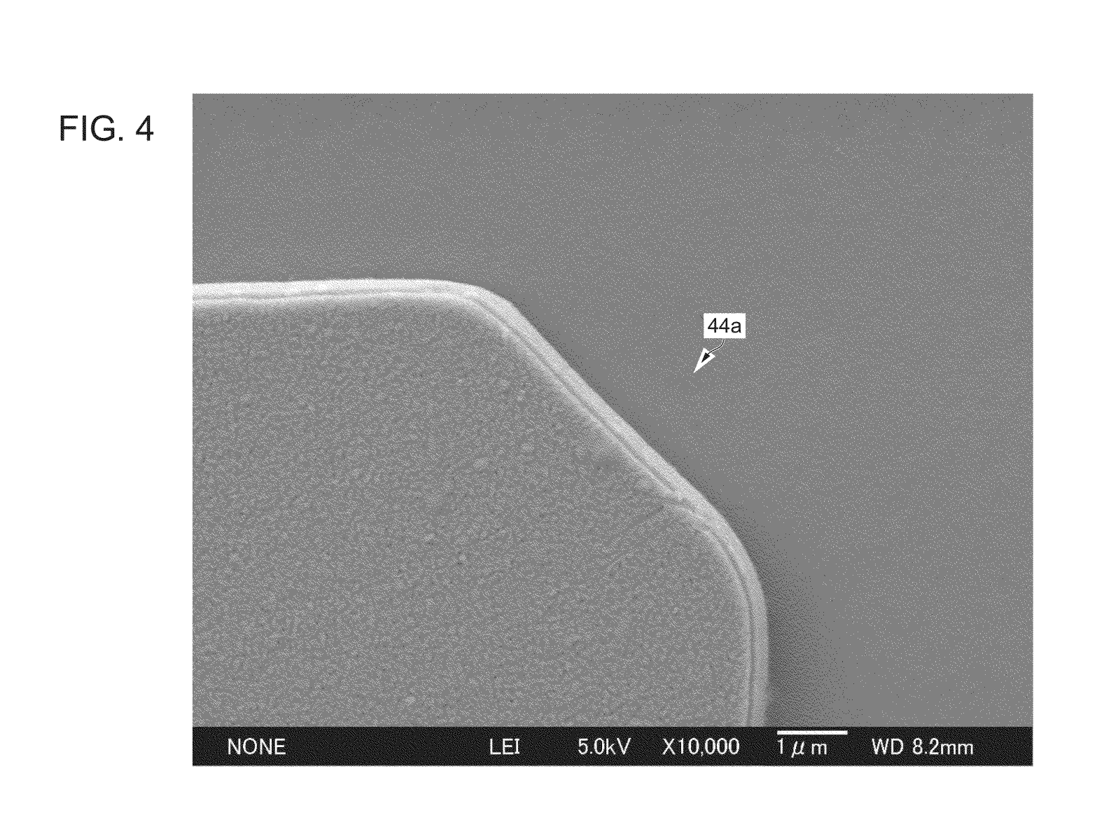

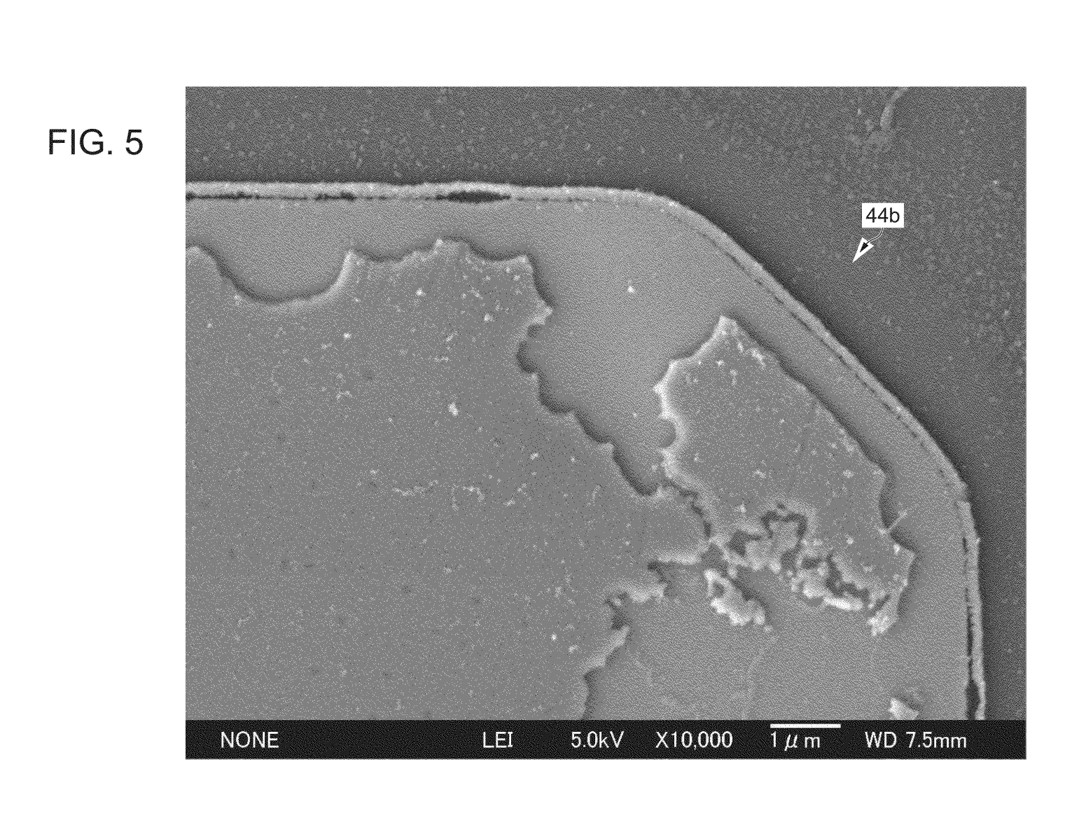

FIGS. 4 to 6B show advantages by the pixel electrode of the embodiment. FIG. 4 shows a result of a plan view (of a pixel electrode 44a) after rectangular wave having an amplitude of 0 V to 10 V (volts) is applied to the pixel electrode 44a with a smaller exposed area of the Ti layer 48 in a predetermined time. FIG. 5 shows a result of a plan view (of a pixel electrode 44b) after rectangular wave having an amplitude of 0 V to 10 V (volts) is applied to the pixel electrode 44a with a larger exposed area of the Ti layer 48 in a predetermined time.

FIGS. 6A and 6B show sections of the pixel electrodes (44a, 44b) used for the above described experiments. Specifically, FIG. 6A is a sectional view of the pixel electrode 44a having the smaller exposed area of the Ti layer 48 and FIG. 6B is a sectional view of the pixel electrode 44b having the larger exposed area of the Ti layer 48. In FIGS. 6A and 6B, only the second interlayer insulating film 42 is shown other than the elements related to the pixel electrode 44 and illustration of the other component elements is omitted for simplification.

As shown in FIG. 6A, regarding the pixel electrode 44a, the width L1 of the part (outer edge portion) of the Ti layer 48 protruding from the Al layer 47 in the plan view is 0.1 μm. Further, the planar area of the pixel electrode 44a and the layer thicknesses of the Al layer 47 and the Ti layer 48 are nearly equal to those of the pixel electrode 44 shown in FIGS. 3A to 3C. Therefore, the exposed area of the Ti layer 48 in the pixel electrode 44a is about 40 μm² in the outer edge portion and about 40 μm² in the end portion, and about 80 μm² in total. Further, the exposed area of the Al layer 47 in the pixel electrode 44a is about 120 μm² in the outer edge portion and about 10000 μm² in the upper surface, and about 10120 μm² in total. Therefore, the ratio between the exposure areas of the Al layer 47 and the Ti layer 48 in the pixel electrode 44a is about 126.5:1.

Further, as shown in FIG. 6B, regarding the pixel electrode 44b, the width L2 of the outer edge portion of the Ti layer 48 is 0.5 μm. Further, the planar area of the pixel electrode 44b and the layer thicknesses of the Al layer 47 and the Ti layer 48 are nearly equal to those of the pixel electrode 44 shown in FIGS. 3A to 3C. Therefore, the exposed area of the Ti layer 48 in the pixel electrode 44b is about 200 μm² in the outer edge portion and about 40 μm² in the end portion, and about 240 μm² in total. Further, the exposed area of the Al layer 47 in the pixel electrode 44a is 10120 μm² equal to that of the pixel electrode 44a. Therefore, the ratio between the exposure areas of the Al layer 47 and the Ti layer 48 in the pixel electrode 44b is about 42.2:1.

As shown in FIG. 4, in the case of the pixel electrode 44a, even after the application of the rectangular wave having the amplitude of 0 V to 10 V (volts) in the predetermined time, corrosion (dissolution) is not caused in the upper surface, i.e., the Al layer 47, and nearly the same condition as that at formation (manufacture) is maintained.

On the other hand, as shown in FIG. 5, when the rectangular wave is applied to the pixel electrode 44b, significant corrosion (dissolution) is caused. The corrosion progresses to exposure of the Ti layer 48 as the under layer, and significantly reduces the reflectivity of the pixel electrode 44b.

As a result, even when the material having the lower electrode potential like Al is used for the surface in the pixel electrode 44 for use in contact with the material containing electrolyte, the material layer having the higher electrode potential like Ti is formed in the under layer and the ratio between the exposed area of Al (Al layer 47) and the exposed area of Ti (Ti layer 48) is appropriately set, and thereby, dissolution (corrosion) of the material layer having the lower electrode potential (Al layer 47) may be suppressed.

As described above, in the reflective display device, the electrodes at the non-display surface side (the pixel electrodes 44 in the embodiment) are formed using the material having the higher reflectivity like Al, and thereby, the display performance may be improved. However, in the case where the electrode including the single layer of Al is used in contact with the material containing electrolyte, corrosion or the like is caused and reliability is damaged. Accordingly, like the pixel electrode 44 (44a) of the embodiment, the material layer having the higher electrode potential, i.e., Ti layer 48 is formed under the Al layer 47 and the ratio between the exposed area of the Al layer 47 and the exposed area of the Ti layer 48 is appropriately set, and thereby, the dissolution (corrosion) of the Al layer 47 may be suppressed and both higher display performance and reliability may be achieved.

### Method of Manufacturing Pixel Electrode

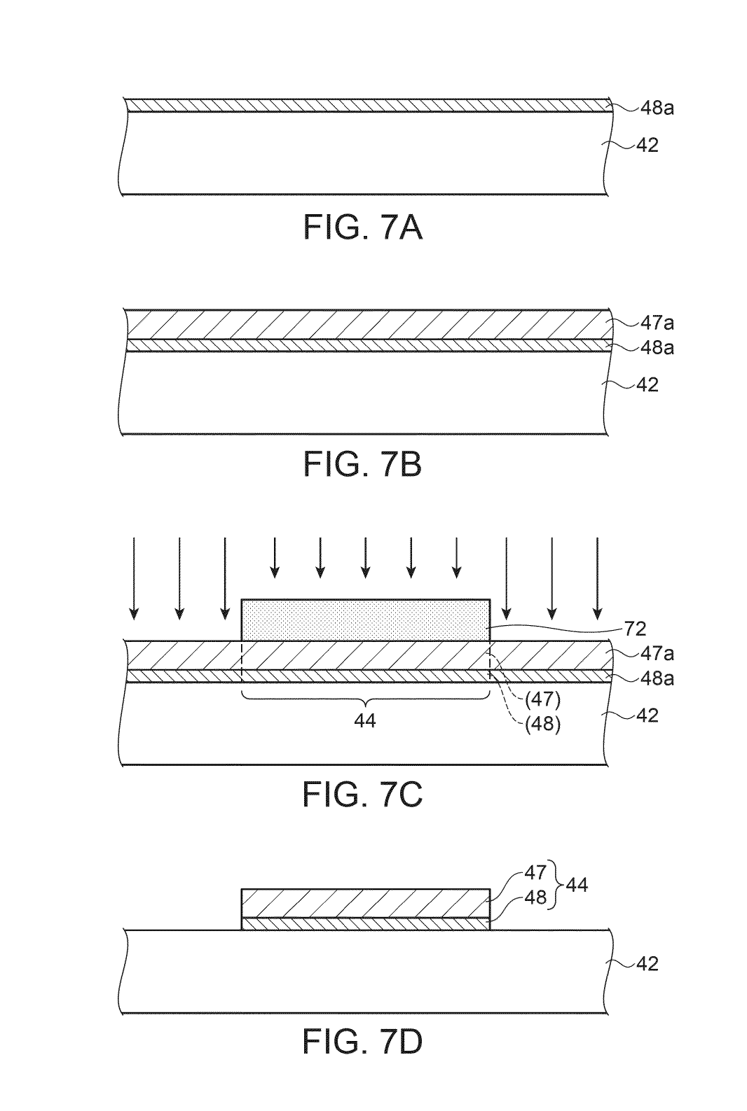

Next, as the second embodiment of the invention, a method of manufacturing a pixel electrode will be explained. FIGS. 7A to 7D are diagrams of steps showing a method of manufacturing the pixel electrode 44 as shown in FIGS. 3A to 3C. In FIGS. 7A to 7D, only the second interlayer insulating film 42 is shown other than the elements related to formation of the pixel electrode 44 and illustration of the other component elements is omitted for simplification like those in FIGS. 6A and 6B.

First, as shown in FIG. 7A, a Ti layer precursor 48a is stacked on the second interlayer insulating film 42. Sputtering is preferably used for the method of stacking (forming) the Ti layer precursor 48a. It is necessary to set the layer thickness of the Ti layer precursor 48a so that the ratio between the exposed areas of both layers in the pixel electrode 44 after formation may be appropriate as described above. The layer thickness of the Ti layer precursor 48a of the embodiment is about 100 nm. The Ti layer precursor 48a is an example of a second conductor layer according to the invention.

Then, as shown in FIG. 7B, an Al layer precursor 47a is stacked on the Ti layer precursor 48a. Like the Ti layer precursor 48a, sputtering is preferably used for the method of stacking (forming) the Al layer precursor 47a. The layer thickness of the Al layer precursor 47a of the embodiment is about 300 nm. The Al layer precursor 47a is an example of a first conductor layer according to the invention.

Then, as shown in FIG. 7C, a photoresist layer 72 is formed in a region in which the pixel electrode 44 is to be formed in the future. Then, anisotropic dry etching using chlorine-based gas is performed, and thereby, the Ti layer precursor 48a and the Al layer precursor 47a are collectively patterned. That is, patterning is performed to avoid production of the level difference between the end portion of the Al layer 47 and the end portion of the Ti layer 48.

Then, as shown in FIG. 7D, the photoresist layer 72 is removed. Through the above described steps, the pixel electrode 44 having the Al layer 47 as the first layer formed at the side of the electrophoretic layer 20 (see FIG. 2) as the display layer and the Ti layer 48 as the second layer formed in contact with the second surface opposed to the first surface of the first layer may be obtained.

According to the method of forming the pixel electrode, the pixel electrode in which the conductor layer having the higher electrode potential and the conductor layer having the lower electrode potential are stacked may be formed by increasing only the single step of forming the conductor layer (metal layer). Further, the exposure of the upper surface of the lower layer (Ti layer 48) may be suppressed, and thereby, the ratio between the exposed area of the Al layer 47 and the exposed area of the Ti layer 48 may be taken to be larger.

The method of manufacturing the pixel electrode is not limited to the above described embodiment. For example, the Al layer 47 may be formed by wet etching and the Ti layer 48 may be formed by dry etching. According to the manufacturing method, the Al layer 47 may be formed to overhang, and thereby, the part in which the Ti layer 48 is exposed may be limited to the end portion only. Therefore, the ratio between the exposed area of the Al layer 47 and the exposed area of the Ti layer 48 may be taken to be larger.

Further, after the formation of the Al layer 47, the Ti layer precursor 48a may be selectively etched using the Al layer 47 as a mask.

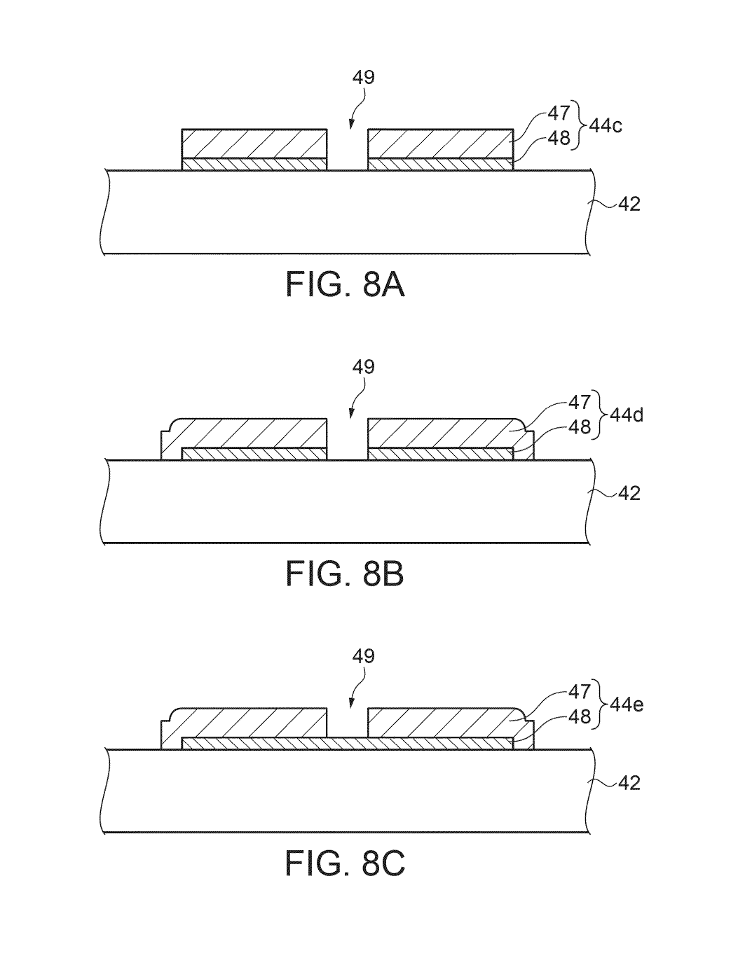

Next, pixel electrodes according to the other embodiments of the invention will be explained. FIGS. 8A to 8C show pixel electrodes according to the third to fifth embodiments. As below, the detailed explanation will be made. In FIGS. 8A to 8C, only the second interlayer insulating film is shown other than the elements related to the configurations of the pixel electrodes 44c to 44e and illustration of the other component elements is omitted for simplification.

FIG. 8A shows the pixel electrode 44c according to the third embodiment of the invention. In the pixel electrode 44c according to the embodiment, a hole 49 penetrating the Al layer 47 and the Ti layer 48 and reaching the second interlayer insulating film 42 is formed. By the hole 49, new end portions are formed for both the Al layer 47 and the Ti layer 48. That is, new exposed parts in the Z-direction are formed. Further, by the new exposed parts, the ratio between the exposed part of the Al layer 47 and the exposed part of the Ti layer 48 may be adjusted.

Here, the areas of the new exposed parts are proportional to the thicknesses of both of the layers. On the other hand, compared to the case without the hole 49, the exposed area of the Al layer 47 is larger. Therefore, the pixel electrode 44c according to the embodiment is effective in the case where the ratio of the exposed area of the Ti layer 48 to the exposed area of the Al layer 47 is desired to be smaller while the layer thickness of the Ti layer 48 is smaller.

Note that the pixel electrode 44c according to the embodiment may be manufactured only by changing the pattern of the photoresist layer 72 shown in FIG. 7C in the manufacturing method according to the second embodiment. Therefore, the ratio of the exposed area of the Ti layer 48 may be made smaller without increasing manufacturing cost.

FIG. 8B shows the pixel electrode 44d according to the fourth embodiment of the invention. In the pixel electrode 44d according to the embodiment, the end portion of the outer periphery of the Ti layer 48 is covered by the Al layer 47. Further, like the above described pixel electrode 44c, a hole 49 penetrating the Al layer 47 and the Ti layer 48 and reaching the second interlayer insulating film 42 is formed. The Ti layer 48 is exposed in the section surfaces of the hole 49 because the end portion of the outer periphery is covered. Therefore, the exposed area of the Ti layer 48 is extremely smaller than that of the pixel electrode 44 of the first embodiment or the like.

When the end portion of the outer periphery of the Ti layer 48 is exposed, the exposed area of the Ti layer 48 is nearly proportional to the layer thickness, however, in the pixel electrode 44d of the embodiment, even when the layer thickness of the Ti layer 48 is larger, the exposed area may be made smaller. Therefore, the pixel electrode of the embodiment is effective in the case where the exposed area of the Ti layer 48 is desired to be smaller and the ratio of the exposed area of the Ti layer 48 to the exposed area of the Al layer 47 is desired to be smaller while the layer thickness of the Ti layer 48 is made larger.

FIG. 8C shows the pixel electrode 44e according to the fifth embodiment of the invention. In the pixel electrode 44e according to the embodiment, the end portion of the outer periphery of the Ti layer 48 is covered by the Al layer 47 like the pixel electrode 44d according to the fourth embodiment. Further, a hole 49 penetrating the Al layer 47 and reaching the Ti layer 48 is formed.

The Ti layer 48 is exposed only in the bottom surface of the hole 49 because the end portion of the outer periphery is covered. Therefore, the exposed area of the Ti layer 48 is extremely smaller than that of the pixel electrode 44 of the first embodiment or the like. Accordingly, like the pixel electrode 44d according to the fourth embodiment, the pixel electrode of the embodiment is effective in the case where the exposed area of the Ti layer 48 is desired to be smaller and the ratio of the exposed area of the Ti layer 48 to the exposed area of the Al layer 47 is desired to be smaller while the layer thickness of the Ti layer 48 is made larger.

Further, the pixel electrode 44e of the embodiment is different from the pixel electrode 94d according to the fourth embodiment in that patterning of the Al layer 47 is easier. For the pixel electrode 44d, it is necessary to etch both the Al layer 47 and the Ti layer 48 at formation of the hole 49. On the other hand, for the pixel electrode 44e of the embodiment, it is necessary to etch (pattern) only the Al layer 47 at formation of the hole 49. Therefore, the etching of the Al layer 47 may be performed by wet etching at lower cost. Furthermore, when the hole 49 is formed by dry etching, the formation may be performed in an optimal condition for the etching of the Al layer 47. Therefore, the pixel electrode 44e in which the exposed area of the Ti layer 48 is made smaller while the layer thickness of the Ti layer 48 is made larger may be realized at lower cost.

### Mounting Terminal

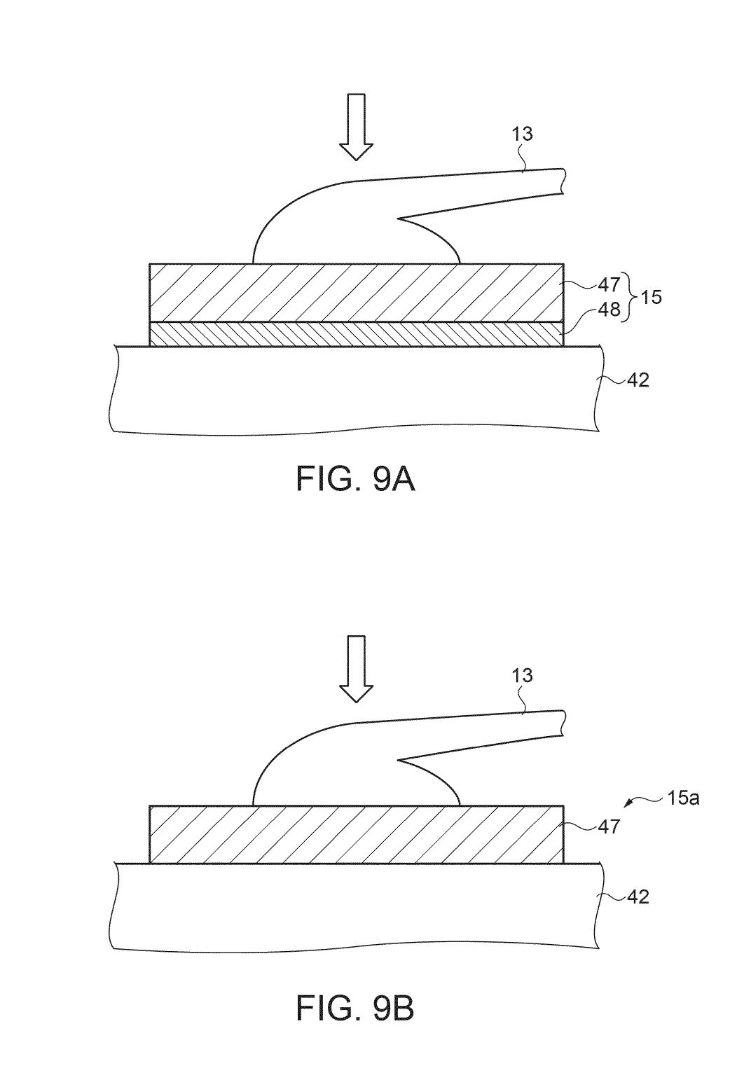

Next, the mounting terminal will be explained as the sixth embodiment of the invention. FIGS. 9A and 9B show the mounting terminal 15 according to the sixth embodiment of the invention with a comparative example. Specifically, FIG. 9A shows the mounting terminal 15 according to the sixth embodiment in which the Al layer 47 and the Ti layer 48 are stacked. FIG. 9B shows a mounting terminal 15a including a single layer of the Al layer 47 as the comparative example. In FIGS. 9A and 9B, only the second interlayer insulating film 42 is shown other than the elements related to the mounting terminal 15 (15a) and illustration of the other component elements is omitted for simplification like the above described respective drawings.

As shown in FIGS. 9A and 9B, the bonding wire 13 is mounted on the mounting terminal 15 (15a). The mounting of the bonding wire 13 obtains electrical and mechanical connection by bringing the end of the bonding wire 13 into close contact with the mounting terminal 15 (15a) while applying strong pressure thereto. Therefore, at bonding (mounting), strong pressure is applied to the mounting terminal 15 (15a) in directions shown by arrows in the drawings. For good bonding, it is necessary to disperse the pressure at bonding. The pressure at bonding is dispersed more smoothly when there is an interlayer (boundary layer) between the layers having different hardness or the like. In the case of the mounting terminal 15a including the single layer of the Al layer 47 as shown in FIG. 9B, there is no interlayer, and the dispersion of the pressure at bonding is slightly deteriorated. On the other hand, the mounting terminal 15 according to the embodiment is formed by stacking the Al layer 47 and the Ti layer 48 as shown in FIG. 9A, and the pressure at bonding is easily dispersed through the interlayer. Further, the mounting terminal 15 may be formed at the same step as that of the pixel electrodes 44 or the like of the respective embodiments. Therefore, according to the mounting terminal 15 of the embodiment, reliability of mounting may be improved. According to the display device having the mounting terminal 15, higher reliability may be realized without increasing manufacturing cost.

The invention is not limited to the above described embodiments, but changes may be appropriately made within a scope not against the gist or the spirit of the invention read from the appended claims and the whole specification, and a pixel electrode and an electrophoretic display device having the pixel electrode with the changes fall within the technical scope of the invention. Other various modified examples than the above described embodiments are conceivable. As below, the explanation will be made by citing modified examples.

### Modified Example 1

The electrophoretic display device 100 of the embodiment is formed using the electrophoretic layer 20 including the microcapsules 24 as shown in FIG. 2. However, the electrophoretic layer 20 is not limited to that including the microcapsules 24. For example, partition walls surrounding the respective pixel electrodes 44 are formed and respective recessed portions formed by the partition walls and the pixel electrodes 44 are filled with the dispersion media 23 containing the black particles 21 and the white particles 22, and thereby, the electrophoretic layer 20 may be formed. In this case, the pixel electrodes 44 are in contact with the dispersion media 23 containing electrolyte, and the advantage of the invention is obtained.

### Modified Example 2

The pixel electrode 44 of the above described embodiments has been explained to be provided in the electrophoretic display device 100. However, the pixel electrode 44 of the embodiment may be applied to another display device, e.g., a liquid crystal display device. In the case of a transmissive liquid crystal display device, one electrode does not require light transmissivity, but requires light reflectivity. Further, the liquid crystal contains electrolyte. Therefore, using the pixel electrode 44 of the embodiment, the display performance and the reliability may be improved.

1. A pixel electrode used in a display device having a display layer provided between a pair of substrates, comprising:
a first layer having a first surface in contact with the display layer; and
a second layer in contact with a second surface opposed to the first surface of the first layer,
wherein an electrode potential of the first layer is lower than an electrode potential of the second layer.

2. The pixel electrode according to claim 1, wherein an end portion of the second layer is not covered by the first layer.

3. The pixel electrode according to claim 1, wherein a hole penetrating the first layer and the second layer is formed.

4. The pixel electrode according to claim 1, wherein a thickness of the first layer is larger than a thickness of the second layer.

5. The pixel electrode according to claim 1, wherein the first layer is formed using Al or an Al alloy.

6. The pixel electrode according to claim 1, wherein the second layer is formed using Ti or a Ti alloy.

7. A display device comprising the pixel electrode according to claim 1.

8. A display device comprising the pixel electrode according to claim 2.

9. A display device comprising the pixel electrode according to claim 3.

10. A display device comprising the pixel electrode according to claim 4.

11. A display device comprising the pixel electrode according to claim 5.

12. A display device comprising the pixel electrode according to claim 6.

13. The display device according to claim 7, further comprising a mounting terminal formed by the first layer and the second layer.

14. The display device according to claim 8, further comprising a mounting terminal formed by the first layer and the second layer.

15. The display device according to claim 9, further comprising a mounting terminal formed by the first layer and the second layer.

16. The display device according to claim 10, further comprising a mounting terminal formed by the first layer and the second layer.

17. The display device according to claim 11, further comprising a mounting terminal formed by the first layer and the second layer.

18. The display device according to claim 12, further comprising a mounting terminal formed by the first layer and the second layer.

19. A method of manufacturing a pixel electrode comprising:
forming a second conductor layer on an insulating layer;
forming a first conductor layer of a material having an electrode potential lower than an electrode potential of a formation material of the second conductor layer on the second conductor layer; and
forming an island-shaped electrode by collectively patterning the first conductor layer and the second conductor layer.
